(19) United States
(12) Patent Application Publication
(10) Pub. No.: US 2012/0170228 A1
(43) Pub. Date: Jul. 5, 2012

(54) CIRCUIT MODULE AND ELECTRIC CONNECTOR

(75) Inventors: Chun-Ming Lai, Yuanli Township (TW); Ming-Hua Tsai, Chiayi City (TW); Shih-Chin Chou, Kaohsiung City (TW)

(73) Assignee: LEXTAR ELECTRONICS CORPORATION, Hsinchu (TW)

(21) Appl. No.: 13/185,926

(22) Filed: Jul. 19, 2011

(30) Foreign Application Priority Data
Dec. 31, 2010 (TW) 99147430

(51) Int. Cl. H05K 1/14; H01R 13/625

(52) U.S. Cl. 361/740; 439/345

(57) ABSTRACT

A circuit module and an electric connector are provided. The electric connector is used for connecting two circuit boards. The electric connector at least includes two bases and a locking element. The bases are disposed on the periphery of the circuit boards and electrically connected with the circuit boards respectively. The locking element is used for locking the bases, such that the circuit boards are mechanically connected with each other and the electric paths thereof are electrically connected.

This application claims the benefit of Taiwan application Serial No. 99147430, filed Dec. 31, 2010, the subject matter of which is incorporated herein by reference.

### BACKGROUND OF THE INVENTION

1. Field of the Invention

The invention relates in general to a circuit module and an electric connector, and more particularly to a circuit module and an electric connector connecting two circuit boards.

2. Description of the Related Art

Along with the advance in technology, various electronic elements are provided. In general, the electronic elements are disposed on circuit boards, and the electronic elements are electrically connected through the circuit boards such that the electronic elements are activated.

As new electronic products continued to be provided, the designers must design the shape of the circuit boards and the layout of the electronic elements according to the needs of the electronic products. For some electronic products, the circuit boards carrying the electronic elements must be connected to each other. However, there are problems and challenge with respect to the currently used methods for connecting the circuit board. Therefore, how to improve the connection between the circuit boards carrying the electronic elements has become a prominent task for the industries.

### SUMMARY OF THE INVENTION

The invention is directed to a circuit module and an electric connector. Through the design of the electric connector, the circuit boards are mechanically connected, and the electric paths thereof are electrically connected.

According to a first aspect of the present invention, a circuit module is provided. The circuit module includes two circuit boards, two electronic elements and an electric connector. The electronic elements are respectively disposed on each of the circuit boards. The electric connector includes two bases and a locking element. The bases are disposed on the periphery of the circuit boards and electrically connected with the circuit boards respectively. The locking element is used for connecting the bases, such that the circuit boards are mechanically connected with each other and the electric paths thereof are electrically connected.

According to a second aspect of the present invention, an electric connector is provided. The electric connector is used for connecting two circuit boards. The electric connector includes two bases and a locking element. The bases are on the periphery of the circuit boards and electrically connected with the circuit boards disposed respectively. The locking element is used for connecting the bases, such that the circuit boards are mechanically connected with each other and the electric paths thereof are electrically connected.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a decomposition diagram of a circuit module according to a first embodiment of the invention;

FIG. 2 shows an assembly diagram of the circuit module of FIG. 1;

FIGS. 3 and 4 are schematic diagrams of a circuit module according to an alternative embodiment;

FIG. 5 shows a side view of the electric connector of FIG. 1;

FIG. 6 shows a decomposition diagram of a circuit module according to a second embodiment of the invention;

FIG. 7 shows an assembly diagram of the circuit module of FIG. 6;

FIGS. 8 and 9 are schematic diagrams of a circuit module according to an alternative embodiment;

FIG. 10 shows a side view of the electric connector of FIG. 6.

### DETAILED DESCRIPTION OF THE INVENTION

Through the design of the bases and the locking of the invention, the circuit boards carrying the electronic elements are mechanically and electrically connected with each other when the locking element connects the bases. A number of embodiments are exemplified below for detailed descriptions not for limiting the scope of protection of the invention.

### First Embodiment

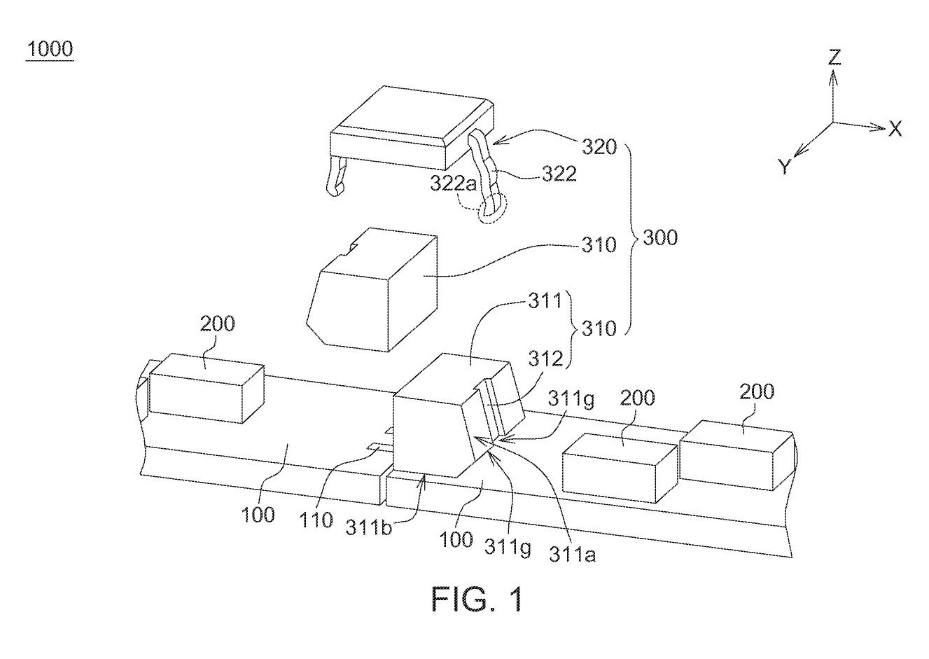

Referring to FIG. 1, a decomposition diagram of a circuit module 1000 according to a first embodiment of the invention is shown. The circuit module 1000 includes at least two circuit boards 100, at least two electronic elements 200 and at least an electric connector 300. The circuit boards 100 are used for carrying and electrically connecting various electronic elements so as to provide specific electrical functions. The circuit boards 100 are respectively realized by such as a single-sided circuit board or a double-sided circuit board. The electronic elements 200 respectively disposed on each of the circuit boards 100 are realized by such as a light emitting diode (light-emitting diode, LED) or a light emitting chip. The electric connector 300 is used for connecting the circuit boards 100 and electrically connecting the electric paths of the electronic elements 200.

As indicated in FIG. 1, a set of electric connector 300 includes two bases 310 and a locking element 320. Each base 310 includes a base body 311 and a first electric contact pin 312. The base body 311 has a recess 311g. One end of the first electric contact pin 312 is disposed in the recess 311 g, and the other end of the first electric contact pin 312 is disposed on the bottom surface 311b of the base body 311. The locking element 320 includes a second electric contact pin 322. A portion of the second electric contact pin 322 is embedded into the recess 311g and used for contacting the first electric contact pin 312.

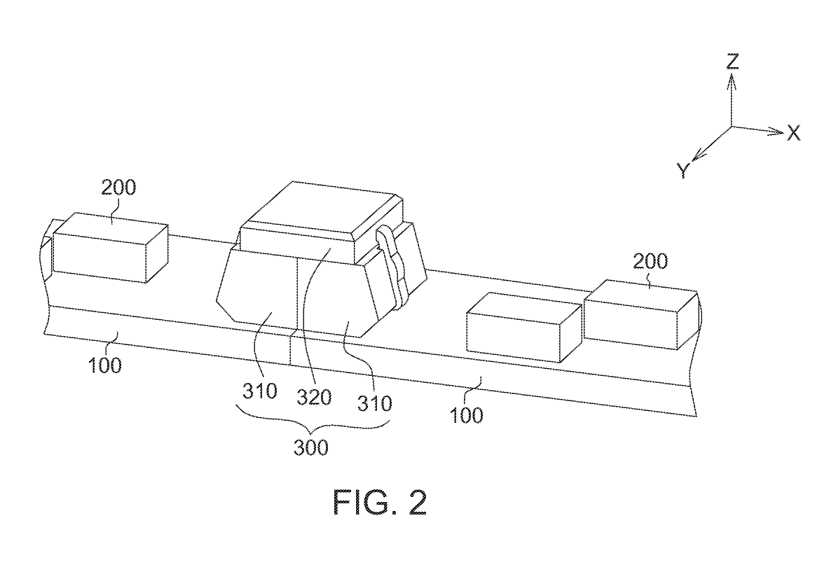

Referring to FIG. 2, an assembly diagram of the circuit module 1000 of FIG. 1 is shown. When the two bases 310 are respectively disposed on the periphery of the two circuit boards 100, the locking element 320 connects the bases 310, such that the circuit boards 100 are mechanically connected with each other.

As indicated in FIG. 1, in terms of electrical connection, one end of the first electric contact pin 312 is disposed on the bottom surface 311 b of the base body 311, the first electric contact pin 312 is soldered on the solder pad 110 of the circuit board 100, and the first electric contact pin 312 is electrically to the electronic elements 200 through the internal traces of the circuit board 100. When the locking element 320 connects the bases 310, through the contact between the second electric contact pin 322 and the first electric contact pin 312, the circuit boards 100 are electrically connected to form an electric path for serially connecting the electronic elements 200.

In addition, the circuit board 100 is bar-shaped, and each of the bases 310 is disposed on one end of the bar-shaped circuit board 100. Thus, when the bases 310 are connected by the locking element 320, two circuit boards 100 will be connected as an even longer bar-shaped structure. In an embodiment, the bases 310 can be disposed on the two ends of each circuit board 100, such that the two ends of each circuit board 100 can be connected to another circuit board 100 through the electric connector 300 of the present embodiment of the invention. Thus, the length of the circuit module 1000 assembled through the electric connector 300 of the present embodiment of the invention can be easily increased or decreased. When a particular circuit board 100 is broken, the broken can be easily replaced without resorting to destructive disassembly. Thus, the said bar-shaped circuit module 1000 is extremely applicable to the bar-shaped structure such as LED tube or display or backlight module.

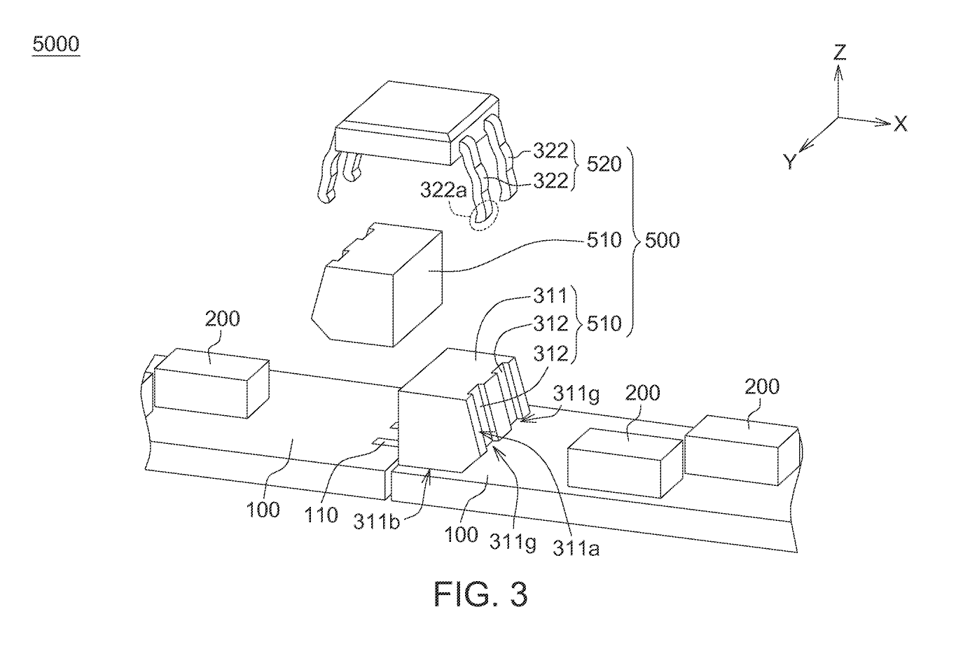

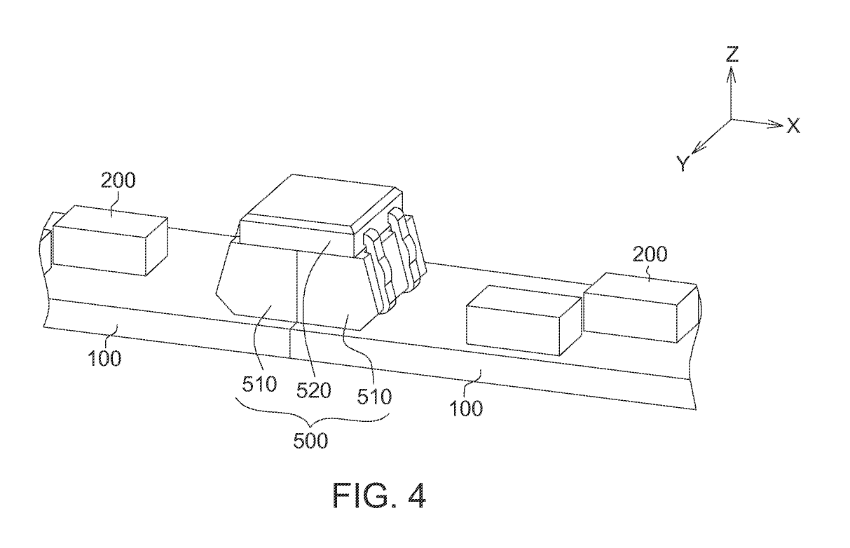

Referring to FIGS. 3 and 4, schematic diagrams of a circuit module 5000 according to an alternative embodiment are shown. In the circuit module 5000 of an alternative embodiment, the number of the recesses 311g of the bases 510 of the power connector 500 and the number of the first electric contact pins 312 can be plural (such as 2 as indicated in FIGS. 3 and 4), and the number of the second electric contact pins 322 of the locking element 520 can be plural (such as 2 as indicated in FIGS. 3 and 4). The functions of mechanical connection and electrical connection can be achieved as long as the numbers of the recesses 311g, the first electric contact pins 312 and the second electric contact pins 322 are consistent.

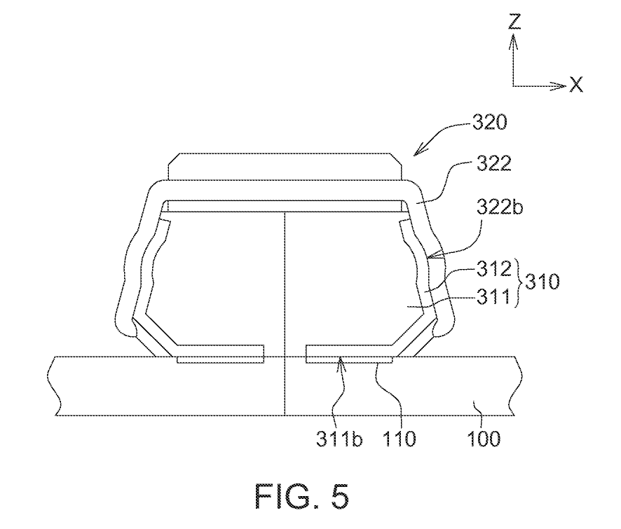

Referring to FIGS. 1 and 5. FIG. 5 shows a side view of the electric connector 300 of FIG. 1. In terms of the relationship between the bases 310 and the locking element 320, each second electric contact pin 322 has two protrusion portions 322a disposed at the two ends of the second electric contact pin 322, and when the second electric contact pin 322 slides along the groove 311g until the protrusion portions 322a reach the terminal end of the groove 311g, the protrusion portions 322a will be connected to the first electric contact pin 312. Thus, the locking element 320 can be firmly connected to the bases 310. In addition, in an embodiment, the number of the protrusion portion 322a can be one or more than one.

### Second Embodiment

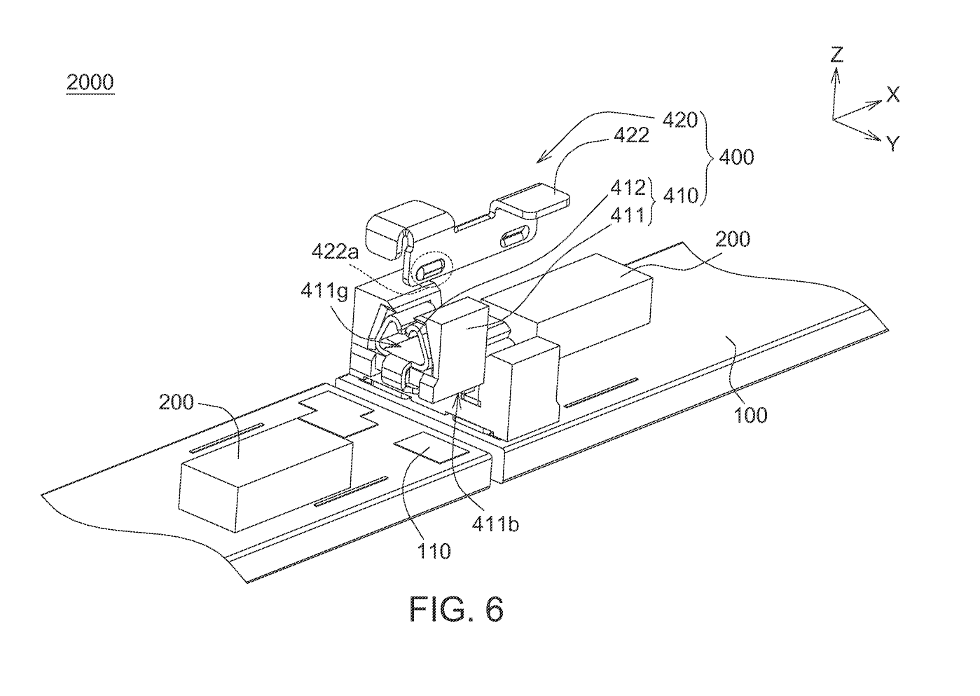

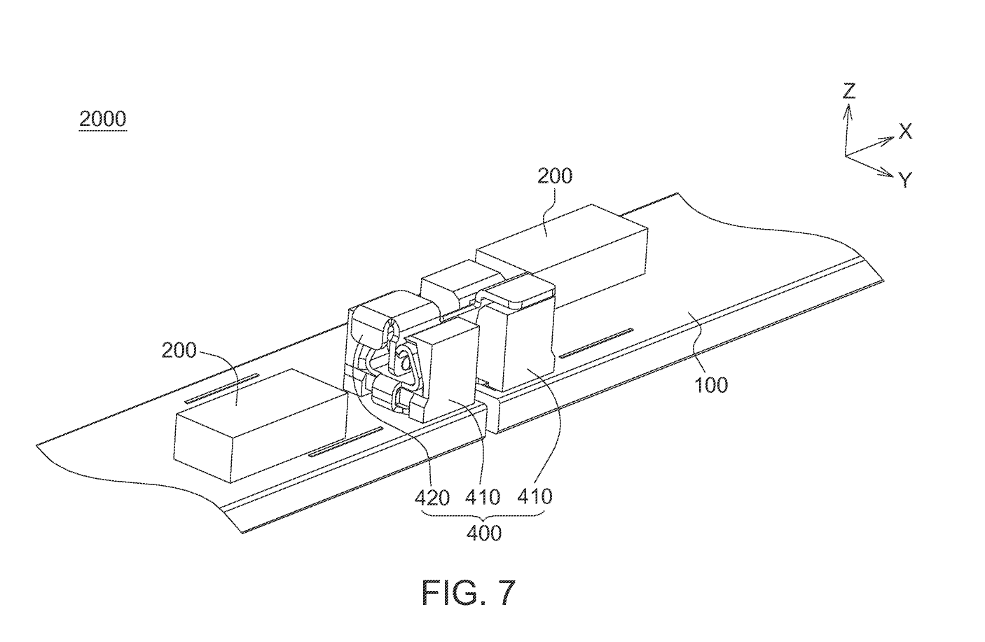

Referring to FIGS. 6 and 7. FIG. 6 shows a decomposition diagram of a circuit module 2000 according to a second embodiment of the invention. FIG. 7 shows an assembly diagram of the circuit module 2000 of FIG. 6. The circuit module 2000 includes at least two circuit boards 100, at least two electronic elements 200 and an electric connector 400. The electric connector 400 is used for connecting the circuit boards 100 and electrically connecting the electric paths of the electronic elements 200.

As indicated in FIG. 6, a set of electric connector 400 includes two bases 410 and a locking element 420. The bases 410 includes a base body 411 and a first electric contact pin 412. The base body 411 has a recess 411g. One end of the first electric contact pin 412 is disposed in the recess 411 g, and the other end of the first electric contact pin 412 is disposed on the bottom surface 411b of the base body 411. The locking element 420 includes a second electric contact pin 422. The second electric contact pin 422 a portion of is embedded into the recess 411 g and used for contacting the first electric contact pin 412.

As indicated in FIG. 7, the two bases 410 are respectively disposed on the periphery of the two circuit boards 100. When the two bases 410 are respectively disposed on the periphery of the two circuit boards 100, the locking element 420 can connect the bases 410, such that the circuit boards 100 are mechanically connected with each other.

As indicated in FIG. 6, in terms of electrical connection, one end of the first electric contact pin 412 is disposed on the bottom surface 411 b of the base body 411, the first electric contact pin 412 is soldered on the solder pad 110 of the circuit board 100, and the first electric contact pin 412 is electrically connected to the electronic elements 200 through the internal traces of the circuit board 200. When the locking element 320 connects the bases 310, through the contact between the second electric contact pin 422 and the first electric contact pin 312, the circuit boards 100 are electrically connected to form an electric path for serially connecting the electronic elements 200.

In addition, the circuit board 100 is bar-shaped, and each of the bases 410 is disposed on one end of the bar-shaped circuit board 100. Thus, when the bases 410 are connected by the locking element 420, two circuit boards 100 will be connected as an even longer bar-shaped structure. In an embodiment, the bases 410 can be disposed on the two ends of each circuit board 100, such that the two ends of each circuit board 100 can be connected to another circuit board 100 through the electric connector 300 of the present embodiment of the invention. Thus, the length of the circuit module 2000 assembled through the electric connector 400 of the present embodiment of the invention can be easily increased or decreased. When a particular circuit board 100 is broken, the broken can be easily replaced without resorting to destructive disassembly.

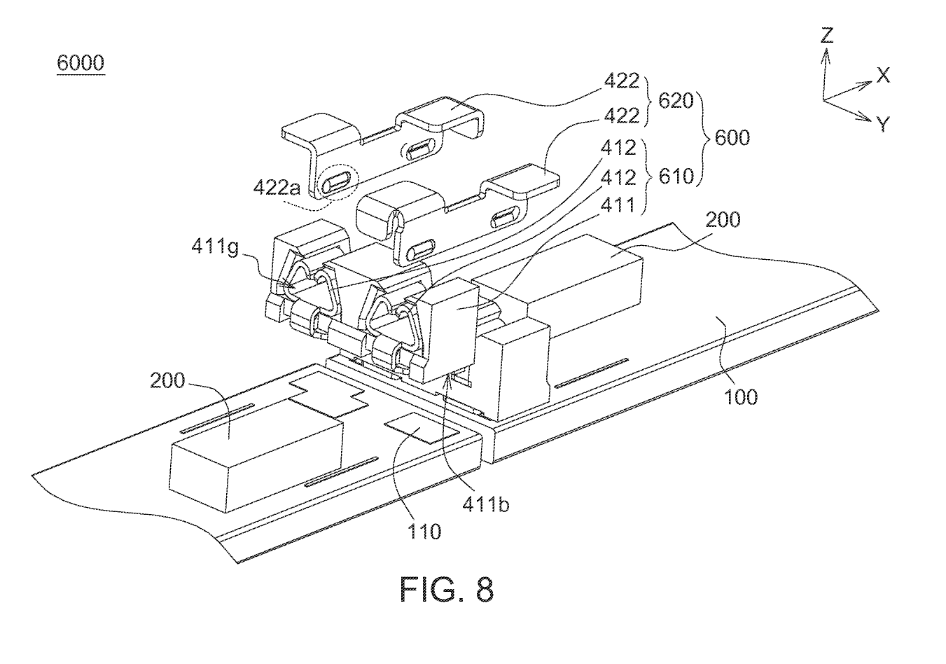

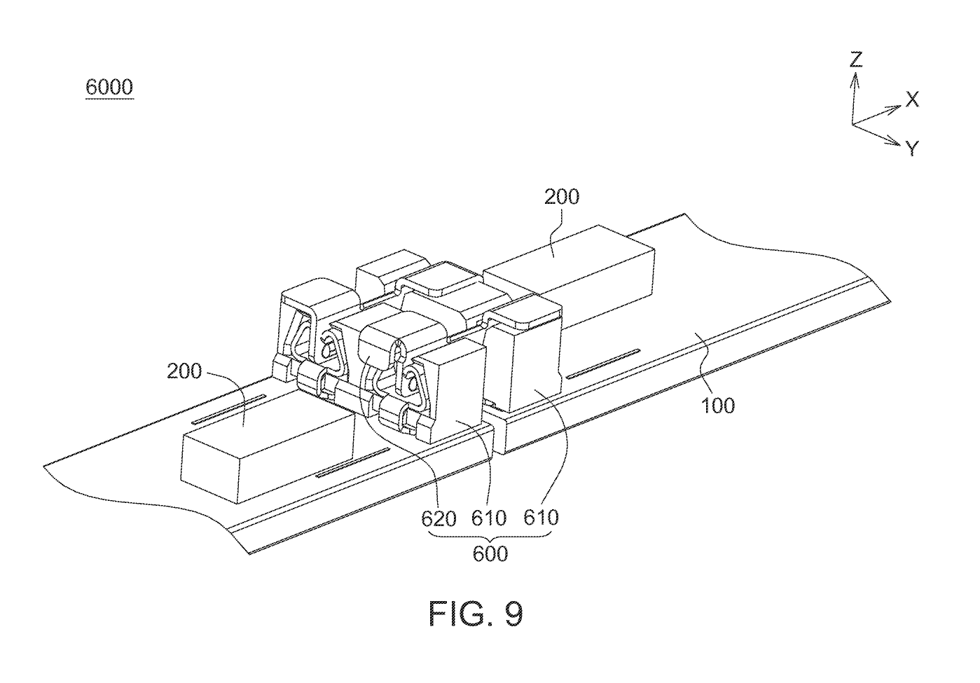

Referring to FIGS. 8 and 9, schematic diagrams of a circuit module 5000 according to an alternative embodiment are shown. In the circuit module 6000 of an alternative embodiment, the number of the recesses 411g of the bases 610 of the power connector 600 and the number of the first electric contact pins 412 can be plural (such as 2 as indicated in FIGS. 8 and 9), and the number of the second electric contact pins 422 of the locking element 620 can be plural (such as 2 as indicated in FIGS. 8 and 9). The functions of mechanical connection and electrical connection can be achieved as long as the numbers of the recesses 411g, the first electric contact pins 412 and the second electric contact pins 422 are consistent.

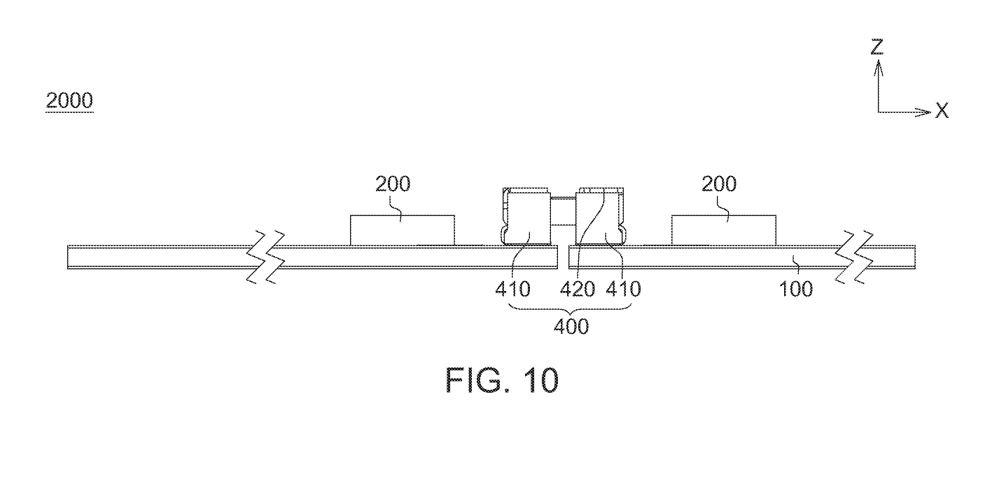

Referring to FIGS. 6 and 10. FIG. 10 shows a side view of the electric connector of FIG. 6. In terms of the relationship between the bases 410 and the locking element 420, each second electric contact pin 422 has two protrusion portions 422a and when the second electric contact pin 422 slides along the groove 411g, the two protrusion portions 422a will be connected to the first electric contact pin 312. Thus, the locking element 320 can be firmly connected to the bases 310. In addition, in an embodiment, the number of the protrusion portion 422a can be one or more than one.

Through the design of the bases and the locking of the invention, the circuit boards carrying the electronic elements are mechanically and electrically connected with each other when the locking element connects the bases.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A circuit module, comprising:
two circuit boards;
two electronic elements disposed on the circuit boards respectively; and
an electric connector, comprising:
two bases disposed on the periphery of the circuit boards and electrically connected with the circuit boards respectively; and
a locking element used for locking the bases, such that the circuit boards are mechanically connected with each other and the electric paths thereof are electrically connected.

2. The circuit module according to claim 1, wherein each of the bases comprises:
a base body having a recess; and
a first electric contact pin, wherein one end of the first electric contact pin is disposed in the recess, the other end of the first electric contact pin is disposed on a bottom surface of the base body, and the first electric contact pin is soldered on each of the circuit boards.

3. The circuit module according to claim 2, wherein the locking element comprises:
a second electric contact pin embedded into the recess and used for contacting the first electric contact pin.

4. The circuit module according to claim 3, wherein the second electric contact pin has a protrusion portion used for coupling to the first electric contact pin.

5. The circuit module according to claim 4, wherein the number of the protrusion portion of the second electric contact pin is plural.

6. The circuit module according to claim 3, wherein the number of the recess or the second electric contact pin is plural.

7. The circuit module according to claim 2, wherein the number of the recess or the first electric contact pin is plural.

8. The circuit module according to claim 1, wherein the bases and the electronic elements are disposed on the same surface of the circuit board.

9. The circuit module according to claim 1, wherein the electronic element is a light emitting diode or a light emitting chip.

10. The circuit module according to claim 1, wherein the locking element is
a fastening element or an engaging element.

11. An electric connector used for connecting two circuit boards, wherein
the electric connector comprises:
two bases disposed on the periphery of the circuit boards and electrically connected with the circuit boards respectively; and
a locking element used for locking the bases, such that the circuit boards are mechanically connected with each other and the electric paths thereof are electrically connected.

12. The electric connector according to claim 11, wherein each of the bases comprises:
a base body having a recess; and
a first electric contact pin, wherein one end of the first electric contact pin is disposed in the recess, the other end of the first electric contact pin is disposed on a bottom surface of the base body, the first electric contact pin is soldered on each of the circuit boards.

13. The electric connector according to claim 12, the locking element comprises:
a second electric contact pin embedded into the recess and used for contacting the first electric contact pin.

14. The electric connector according to claim 13, wherein the second electric contact pin has a protrusion portion used for coupling to the first electric contact pin.

15. The electric connector according to claim 14, wherein the number of the protrusion portion of the second electric contact pin is plural.

16. The electric connector according to claim 13, wherein the number of the recess or the second electric contact pin is plural.

17. The electric connector according to claim 12, wherein the number of the recess or the first electric contact pin is plural.

18. The electric connector according to claim 11, wherein the locking element is a fastening element or an engaging element.
